(19) United States
(12) Patent Application Publication
(10) Pub. No.: US 2025/0144757 A1
(43) Pub. Date: May 8, 2025

(54) HOLDING MEMBER AND METHOD OF MANUFACTURING HOLDING MEMBER

(71) Applicant: Niterra Co., Ltd., Nagoya-shi, Aichi (JP)

(72) Inventors: Hideki UEMATSU, Nagoya-shi (JP); Yuya MINAMIHATA, Nagoya-shi (JP)

(21) Appl. No.: 18/833,140

(22) PCT Filed: Mar. 15, 2023
(86) PCT No.: PCT/JP2023/010019

§ 371 Date: Jul. 25, 2024

(30) Foreign Application Priority Data
Dec. 28, 2022 (JP) 2022-211186

(51) Int. Cl. B23Q 3/154; B23K 26/0622; B23K 26/364; H02N 13/00

(52) U.S. Cl. CPC B23Q 3/154; B23K 26/0624; B23K 26/364; H02N 13/00

(57) ABSTRACT

A holding member contains alpha-type alumina as a main component and is configured to hold a target object. The holding member has a holding surface that is a surface on which the target object is to be held. The holding surface has a projection and a recess formed thereon and therein. A bottom surface that defines a bottom portion of the recess contains gamma-type alumina.

### TECHNICAL FIELD

The present invention relates to a holding member and a method of manufacturing the holding member.

### BACKGROUND ART

A holding member that holds a target object by electrostatic attraction is known. For example, PTL 1 discloses an electrostatic chuck that includes a ceramic member serving as a holding member and in which a recess is formed in a holding surface of the ceramic member by blasting, the holding surface being a surface on which a target object is to be held. The blasting is a process of grinding the holding surface by causing media to collide with the holding surface.

### CITATION LIST

### Patent Literature

PTL 1: Japanese Unexamined Patent Application Publication No. 2020-129632

### SUMMARY OF INVENTION

### Technical Problem

However, in the electrostatic chuck described in PTL 1, the recess is formed in the holding member as a result of collision of media, and thus, there is a possibility that microcracks will be generated in the recess or that strain will be accumulated on a surface of the recess. In the case where microcracks are generated in the recess, particles may sometimes be generated starting from the microcracks due to thermal stress that is generated in the holding member in the process of heating and cooling the holding member, which is holding the target object (in the process of a thermal cycle). In addition, accumulation of strain in the recess induces generation of cracks during use of the holding member, and particles may sometimes be generated starting from the cracks. Therefore, there is still room for improvement in suppressing generation of particles.

The present invention has been made to solve at least some of the above-described problems, and it is an object of the present invention to provide a technology capable of suppressing generation of particles.

### Solution to Problem

The present invention has been made to solve at least some of the above-described problems and can be implemented in the following aspects.

(1) An aspect of the present invention provides a holding member. The holding member contains alpha-type alumina as a main component and is configured to hold a target object. The holding member has a holding surface that is a surface on which the target object is to be held. The holding surface has a projection and a recess formed thereon and therein. A bottom surface that defines a bottom portion of the recess contains gamma-type alumina.

In accordance with this configuration, the bottom surface defining the bottom portion of the recess that is formed in the holding surface, which is a surface on which the target object is to be held, contains gamma-type alumina that has a lower Young's modulus than alpha-type alumina, which is the main component of the holding member. Thus, among the thermal stress that is generated in the holding member in the process of a thermal cycle, the thermal stress that is generated in the bottom surface of the recess can be reduced. Therefore, generation of microcracks in the bottom surface of the recess due to thermal stress can be suppressed, and thus, generation of particles can be suppressed.

(2) In the holding member in accordance with the above-described aspect, the bottom surface may further include an amorphous portion.

In accordance with this configuration, the bottom surface of the recess includes, in addition to gamma-type alumina, the amorphous portion that has a lower Young's modulus than gamma-type alumina. Thus, among the thermal stress generated in the holding member in the process of the thermal cycle, the thermal stress that is generated in the bottom surface of the recess can be further reduced. Further reduction of the thermal stress further suppresses the generation of microcracks, which in turn leads to further suppression of the generation of particles.

(3) In the holding member in accordance with the above-described aspect, a proportion of gamma-type alumina contained in the bottom surface may be 5% or more and 20% or less.

Since gamma-type alumina has a lower Young's modulus than alpha-type alumina, an appropriate amount of gamma-type alumina contained in the bottom surface of the recess contributes to reduction of the thermal stress that is generated in the holding member in the process of the thermal cycle. On the other hand, gamma-type alumina has a lower plasma resistance than alpha-type alumina, and thus, when an excessive amount of gamma-type alumina is contained in the bottom surface of the recess, gamma-type alumina itself can be a generation source of particles. In accordance with this configuration, the gamma-type alumina contained in the bottom surface of the recess can contribute to reduction of the thermal stress while it is suppressed from becoming a generation source of particles.

(4) Another aspect of the present invention provides a method of manufacturing a holding member.

The method of manufacturing a holding member includes a recess formation step of forming a recess in a processing target surface of a member, the member containing alpha-type alumina as a main component, by irradiating the processing target surface with an ultrashort pulse laser beam. In accordance with this configuration, gamma-type alumina and an amorphous portion are included in the recess formed by irradiating the processing target surface of the member, which contains alpha-type alumina as its main component, with the ultrashort pulse laser beam. Thus, among thermal stress that is generated in the holding member in the process of a thermal cycle, the thermal stress that is generated in a bottom surface of the recess can be reduced. Therefore, in accordance with this configuration, generation of microcracks in the bottom surface of the recess due to thermal stress can be suppressed, and thus, the holding member in which generation of particles is suppressed can be manufactured.

(5) An aspect of the present invention provides a holding member. The holding member contains a ceramic as a main component and is configured to hold a target object. The holding member has a holding surface that is a surface on which the target object is to be held. At least a portion of a surface of the holding surface is constituted by first ceramic crystal grains, and a portion that is located further toward the inside than the holding surface is constituted by second ceramic crystal grains. First grain diameters that are the grain diameters of the first ceramic crystal grains are smaller than second grain diameters that are the grain diameters of the second ceramic crystal grains.

In accordance with this configuration, at least the portion of the surface of the holding surface is constituted by the first ceramic crystal grains, and the portion of the holding member, the portion being located further toward the inside than the holding surface, is constituted by the second ceramic crystal grains. In addition, the first grain diameters, which are the grain diameters of the first ceramic crystal grains, are smaller than the second grain diameters, which are the grain diameters of the second ceramic crystal grains. Thus, at least the portion of the surface of the holding surface is constituted by the first ceramic crystal grains with the first grain diameters, which are smaller than the second grain diameters, so that, the sizes of particles that are generated from the holding surface during use of the holding member can be reduced. Furthermore, the first ceramic crystal grains correspond to the ceramic crystal grains obtained by shaving portions of the second ceramic crystal grains, and thus, the surface constituted by the first ceramic crystal grains include ceramic crystal grains whose interiors (portions of the crystal grains that are located further toward the inside than grain boundaries) are exposed toward the surface. In other words, in such a surface, the area of the grain boundaries that are exposed at the surface is reduced, so that the plasma resistance of the holding surface including such a surface can be improved.

(6) In the holding member in accordance with the above-described aspect, the holding surface has a projection and a recess formed thereon and therein, and the surface may be a bottom surface that defines the recess.

In accordance with this configuration, the bottom surface defining the recess is constituted by the first ceramic crystal grains. Thus, when the holding member holds the target object, the sizes of particles generated from the holding surface by an inert gas flowing between the target object and the recess can be reduced.

(7) In the holding member in accordance with the above-described aspect, the surface may be a laser-processed surface.

In accordance with this configuration, the laser-processed surface, which is a surface that has undergone laser processing, is a surface that is formed by finely shaving each crystal grain from a grain boundary toward the interior of the grain, and thus, the first grain diameters of the first ceramic crystal grains are smaller than the second grain diameters. Thus, it is possible to accurately provide the holding member in which the first grain diameters are smaller than the second grain diameters. In addition, the laser-processed surface can have a smaller surface roughness than a blasted surface that has undergone blasting in which a crystal grain is dislodged in its entirety along a grain boundary. In other words, an increase in surface area due to surface roughness can be reduced. As a result, the surface area that is to be subjected to plasma corrosion is reduced, and thus, generation of particles due to plasma corrosion can be suppressed.

Note that the present invention can be implemented in various aspects. For example, the present invention can be implemented in aspects such as a holding member, an electrostatic chuck including an electrostatic electrode that generates electrostatic attraction on a holding member and on a holding surface of the holding member, a vacuum chuck, a ceramic heater, semiconductor production equipment, a component including these, a method of manufacturing these, and so on.

### BRIEF DESCRIPTION OF DRAWINGS

FIG. 1 is an explanatory diagram schematically illustrating a cross-sectional configuration of an electrostatic chuck of a first embodiment.

FIG. 2 is an explanatory diagram illustrating a process of forming recesses.

FIG. 3 is a schematic diagram illustrating shapes of ceramic crystal grains.

### DESCRIPTION OF EMBODIMENTS

### First Embodiment

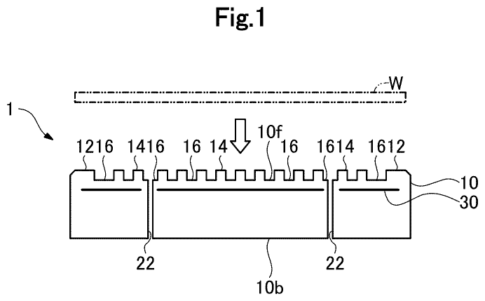

FIG. 1 is an explanatory diagram schematically illustrating a cross-sectional configuration of an electrostatic chuck 1 of the first embodiment. The electrostatic chuck 1 is a device that attracts and holds a semiconductor wafer W, which is a target object, by electrostatic attraction. In FIG. 1, an arrow indicates a direction in which the semiconductor wafer W is attracted to the electrostatic chuck 1. For example, the electrostatic chuck 1 is used to fix the semiconductor wafer W in place in a vacuum chamber of semiconductor production equipment. The electrostatic chuck 1 includes a holding member 10 and an electrostatic electrode 30.

The holding member 10 is a member that has a disc-like shape and holds the semiconductor wafer W, which is a target object. The holding member 10 contains alpha-type alumina as a main component. The main component is a component having the highest volume fraction. The holding member 10 has a holding surface 10f and a rear surface 10b. The holding surface 10f is a surface that has a circular shape and on which the semiconductor wafer W is to be held. The rear surface 10b is a surface that has a circular shape and that is located opposite the holding surface 10f.

The holding surface 10f has a ring-shaped projection 12, a plurality of projections 14, and a plurality of recesses 16 formed thereon and therein. The ring-shaped projection 12 is formed along an outer edge of the holding surface 10f. Each of the projections 14 is formed in an area surrounded by the ring-shaped projection 12. Each of the recesses 16 is formed between the projections 14. In other words, in the area surrounded by the ring-shaped projection 12, the positions at which the recesses 16 are formed correspond to positions at which the projections 14 are not formed. In the present embodiment, when the holding surface 10f is viewed from a direction facing the holding surface 10f (when viewed in plan view), the recesses 16 are arranged in a scattered manner on the circular holding surface 10f, and the proportion of the recesses 16 in the holding surface 10f is 90% or more.

A plurality of through-flow passages 22 are formed inside the holding member 10. Each of the through-flow passages 22 is a flow passage extending between the holding surface 10f and the rear surface 10b and is a flow passage for supplying an inert gas, such as helium gas, supplied from the side on which the rear surface 10b is present to the side on which the holding surface 10f is present. The through-flow passages 22 are connected to the recesses 16 on the side on which the holding surface 10f is present.

The electrostatic electrode 30 is a member that has a disc-like shape and that is provided inside the holding member 10. The electrostatic electrode 30 is made of an electrically conductive material such as tungsten or molybdenum. The electrostatic electrode 30 generates electrostatic attraction on the holding surface 10f as a result of electric power being supplied thereto from an external power supply (not illustrated). The semiconductor wafer W is attracted toward the holding surface 10f by this electrostatic attraction, so that the semiconductor wafer W is held on the holding surface 10f.

When the electrostatic attraction is generated on the holding surface 10f, the semiconductor wafer W is held on the holding surface 10f by being in contact with the ring-shaped projection 12 or the projections 14. In such a state where the semiconductor wafer W is held on the holding surface 10f, the inert gas is supplied between the semiconductor wafer W and the holding surface 10f in order to increase the thermal conductivity between the semiconductor wafer W and the holding surface 10f. More specifically, the inert gas is supplied from the side on which the rear surface 10b is present to the side on which the holding surface 10f is present by passing through the through-flow passages 22 and the recesses 16. The inert gas supplied to the side on which the holding surface 10f is present flows through a space between the semiconductor wafer W and the recesses 16 and diffuses throughout the entire space.

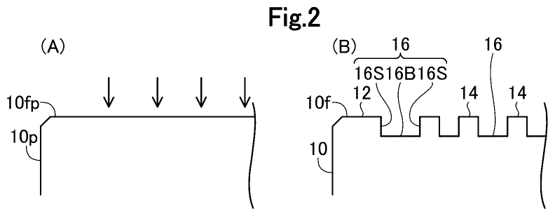

In FIG. 2, (A) and (B) are each an explanatory diagram illustrating a process of forming the recesses 16. A portion of a processing target member 10p that is to be a base of the holding member 10 is illustrated in (A) of FIG. 2. The processing target member 10p has a processing target surface 10fp. The processing target surface 10fp is a surface that is to be the holding surface 10f of the holding member 10 illustrated in FIG. 1 and corresponds to the holding surface 10f before the ring-shaped projection 12, the plurality of projections 14, and the plurality of recesses 16 are formed. Laser processing is performed on recess formation regions of the processing target surface 10fp that are not illustrated and in which the recesses 16 are to be formed, so that the recesses 16 are formed in these recess formation regions. Laser processing is a process of radiating a laser beam toward a processing target. Arrows illustrated in (A) of FIG. 2 each indicate a laser beam that is radiated during the laser processing. As a result of the formation of the plurality of recesses 16, each of the recesses 16 is formed in a corresponding one of the recess formation regions, so that portions adjacent to the recesses 16 become the ring-shaped projection 12 and the plurality of projections 14 as illustrated in (B) of FIG. 2, which will be described later.

In the present embodiment, a laser that is used for the laser processing is an ultrashort pulse laser. The ultrashort pulse laser is a laser having a pulse width in a range from a femtosecond region (10-15) to a picosecond region (10-10) and has high energy density. When this ultrashort pulse laser is used for forming the recesses 16, the pulse width is shorter than the time required for heat to diffuse from a processing target portion that is irradiated with a laser beam, and the material constituting the processing target portion is instantaneously evaporated before the heat is transmitted to the periphery of the processing target portion. Therefore, precise processing with less thermal influence can be performed.

A portion of the holding member 10 is illustrated in (B) of FIG. 2. The recesses 16 have side surfaces 16S and bottom surfaces 16B. The side surfaces 16S are surfaces that define side portions of the recesses 16. The bottom surfaces 16B are surfaces that define bottom portions of the recesses 16. In other words, the side surfaces 16S and the bottom surfaces 16B define the recesses 16.

As mentioned above, the holding member 10 contains alpha-type alumina as its main component, and thus, the processing target member 10p ((A) of FIG. 2), which is to be subjected to laser processing, also contains alpha-type alumina as a main component. The side surfaces 16S and the bottom surfaces 16B are formed by performing laser processing on the processing target surface 10fp of the above-described processing target member 10p, and among these side and bottom surfaces, at least the bottom surfaces 16B contain gamma-type alumina that is formed as a result of alpha-type alumina being melted during the laser processing, cooled, and transformed. In addition, the bottom surfaces 16B further include an amorphous portion. In the amorphous portion, the crystal structure is disordered compared to that in alpha-type alumina and that in gamma-type alumina. Such an amorphous portion seems to be generated as a result of alpha-type alumina being cooled more rapidly compared with the case of cooling at the time of transformation of melted alpha-type alumina into gamma-type alumina. Note that, when the recesses 16 are formed by performing blasting on the processing target surface 10fp, alpha-type alumina does not transform into gamma-type alumina, and thus, gamma-type alumina is not contained in the bottom surfaces 16B, which define the bottom portions of the recesses 16.

The presence of gamma-type alumina in the bottom surfaces 16B is confirmed by the relative intensity becoming stronger near a peak position of gamma-type alumina in an XRD pattern that is obtained by measuring the holding surface 10f using thin-film XRD. The thin-film XRD is a type of XRD in which an X-ray is incident on a surface of a measurement target at a low angle of incidence (e.g., 1 degree or smaller). In the present embodiment, measurements are performed by causing an X-ray to be incident on the bottom surfaces 16B at an angle of incidence of 2 degrees. When it is confirmed that the relative intensity becomes stronger near the peak position of gamma-type alumina in the measurement results, gamma-type alumina is presumed to be contained in the bottom surfaces 16B. In addition, the presence of the amorphous portion in the bottom surfaces 16B is confirmed by the presence of a halo pattern in an XRD pattern obtained by measuring the holding surface 10f using thin-film XRD. Note that the absence of gamma-type alumina in the bottom surfaces 16B of the recesses 16 formed by performing blasting on the processing target surface 10fp can be confirmed by the relative intensity not becoming stronger near a peak position of gamma-type alumina in an XRD pattern that is obtained by measuring the bottom surfaces 16B using thin-film XRD.

In the holding member 10, the proportion of gamma-type alumina contained in the bottom surfaces 16B is 5% or more and 20% or less. Here, the term “proportion” refers to the intensity ratio of gamma-type alumina to alpha-type alumina. This intensity ratio is calculated by dividing the intensity of the peak at the (400) plane of gamma-type alumina among the peaks measured by thin-film XRD for gamma-type alumina by the intensity of the peak of the (113) plane of alpha-type alumina among the peaks measured by thin-film XRD for alpha-type alumina.

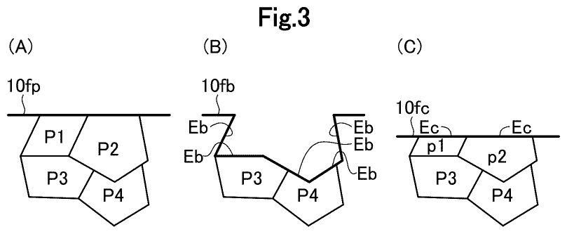

In FIG. 3, (A) to (C) are schematic diagrams illustrating shapes of ceramic crystal grains. Here, the term “ceramic crystal grains” refers to crystal grains of alumina. The shapes of ceramic crystal grains constituting a portion located near the processing target surface 10fp are illustrated in (A) of FIG. 3. The lines defining crystal grains P1 to P4 each represent a grain boundary. The shapes of the ceramic crystal grains when blasting is performed on the processing target surface 10fp in (A) of FIG. 3 are illustrated in (B) of FIG. 3. Blasting is a process of projecting an abrasive material toward a processing target. A processed surface 10fb that is illustrated in (B) of FIG. 3 is a surface exposed by grinding the processing target surface 10fp through the blasting. The shapes of the ceramic crystal grains when laser processing is performed on the processing target surface 10fp illustrated in (A) of FIG. 3 are illustrated in (C) of FIG. 3. A processed surface 10fc that is illustrated in (C) of FIG. 3 is a surface exposed by shaving the processing target surface 10fp through the laser processing. The processing target surface 10fp, the processed surface 10fb, and the processed surface 10fc are each indicated by a bold line in (A) to (C) of FIG. 3.

As will be described with reference to (A) to (C) of FIG. 3, the grain diameters of the ceramic crystal grains constituting a processed surface vary depending on the type of processing employed when the processing target surface 10fp is processed. Exposed portions Eb of the processed surface 10fb illustrated in (B) of FIG. 3 are portions where the grain boundaries are exposed due to dislodging of the crystal grains P1 and P2 resulting from blasting performed on the processing target surface 10fp. In blasting, a crystal grain is dislodged in its entirety along a grain boundary by projecting an abrasive material, and thus, as illustrated in (B) of FIG. 3, the surface roughness of the processed surface 10fb is likely to be large, and the area of the grain boundaries exposed at the processed surface 10fb is also likely to be large. In contrast, exposed portions Ec of the processed surface 10fc illustrated in (C) of FIG. 3 are portions where the interiors of grains (portions located further toward the inside than grain boundaries) are exposed due to partial shaving of the crystal grains P1 and P2 resulting from laser processing performed on the processing target surface 10fp. Crystal grains p1 and p2 illustrated in (C) of FIG. 3 correspond to the crystal grains P1 and P2 that have been partially shaved. In laser processing, each crystal grain is finely shaved from a grain boundary toward the interior of the grain, and thus, as illustrated in (C) of FIG. 3, the surface roughness of the processed surface 10fc is less likely to be large, and the area of the grain boundaries exposed at the processed surface 10fc is also less likely to be large. In addition, the interiors of the grains are likely to be exposed at the processed surface 10fc, and thus, the grain diameters of the ceramic crystal grains constituting a surface of the processed surface 10fc are likely to be smaller than those in the case of the processing target surface 10fp and the case of the processed surface 10fb.

As described above, the plurality of recesses 16 are formed by performing laser processing on the processing target surface 10fp, and at least the bottom surfaces 16B, among the side surfaces 16S and the bottom surfaces 16B, correspond to laser-processed surfaces. Thus, since the ceramic crystal grains constituting the bottom surfaces 16B are at least partially shaved by laser processing, as described with reference to (C) of FIG. 3, the grain diameters of the ceramic crystal grains (e.g., the crystal grains p1 and p2 in (C) of FIG. 3) are smaller than the grain diameters of the ceramic crystal grains (e.g., the crystal grains P3 and P4 in (C) of FIG. 3) constituting a portion located further toward the inside than the holding surface 10f. In the following description, the ceramic crystal grains constituting the bottom surfaces 16B will be referred to as first ceramic crystal grains, and the grain diameters of the first ceramic crystal grains will be referred to as first grain diameters. In addition, the ceramic crystal grains constituting the portion of the holding member 10, the portion being located further toward the inside than the holding surface 10f, will be referred to as second ceramic crystal grains, and the grain diameters of the second ceramic crystal grains will be referred to as second grain diameters. In other words, in the holding member 10, the bottom surfaces 16B are surfaces constituted by the first ceramic crystal grains, and the first grain diameters are smaller than the second grain diameters. Note that the first ceramic crystal grains and the second ceramic crystal grains are both grains constituting the holding member 10. In other words, even in the case where the holding surface 10f is coated, the crystal grains constituting the layer formed by the coating are not the first ceramic crystal grains. The first ceramic crystal grains and the second ceramic crystal grains are made of the same ceramic material. In other words, the size comparison between the first grain diameters and the second grain diameters is performed between crystal grains made of the same material.

The fact that the first grain diameters are smaller than the second grain diameters can be confirmed by comparing a result (XRD pattern) that is obtained by measuring the holding surface 10f using thin-film XRD with a result (XRD pattern) that is obtained by measuring the inside of the holding member 10 using normal XRD. Normal XRD is a type of XRD in which an X-ray is incident on the interior of a measurement target. In the comparison, values of the half-widths measured by thin-film XRD and XRD are used. More specifically, the fact that the first grain diameters are smaller than the second grain diameters is confirmed by the fact that the value of the half-width in the measurement result of thin-film XRD is larger than the value of the half-width in the measurement result of XRD. In addition, the values of the first grain diameters and the values of the second grain diameters can be calculated from the values of the half-widths by using the Scherrer equation expressed by Equation (1) below:

r=(K·λ)/βcos θ (1)

where r denotes grain diameter, K denotes Scherrer constant, λ denotes wavelength of X-ray used for measurement, β denotes half-width, and θ denotes Bragg angle.

In the present embodiment, since the ceramic member 10p ((A) of FIG. 2), which is to be subjected to laser processing, contains alpha-type alumina, a portion of the holding member 10, the portion being located further toward the inside than the holding surface 10f, also contains alpha-type alumina. In contrast, portions in the vicinity of at least the bottom surfaces 16B, among the side surfaces 16S and the bottom surfaces 16B, contain gamma-type alumina, which is formed as a result of alpha-type alumina being cooled and transformed through laser processing. The presence of gamma-type alumina is confirmed by the relative intensity becoming stronger near a peak position of gamma-type alumina in an XRD pattern that is obtained by measuring the holding surface 10f using thin-film XRD.

In addition, the first ceramic crystal grains correspond to the ceramic crystal grains obtained by shaving portions of the second ceramic crystal grains by laser processing, and thus, the ceramic crystal grains constituting at least the bottom surfaces 16B, among the side surfaces 16S and the bottom surfaces 16B defining the recesses 16, include ceramic crystal grains (e.g., the crystal grains p1 and p2 illustrated in (C) of FIG. 3) with exposed interiors facing surfaces of the bottom surfaces 16B.

In an observation of a cross-section of the holding member 10 by using an SEM, a plurality of very small pores (cavities) were confirmed in the vicinity of the bottom surfaces 16B. In addition, the shapes of the ceramic crystal grains constituting the bottom surfaces 16B were likely to be rounded compared with those constituting the bottom surfaces of the recesses formed by blasting. The lengths of cracks extending from the inside of the holding member 10 to the bottom surfaces 16B were likely to be shorter than those in the case of the bottom surfaces of the recesses formed by blasting. In addition, the number of the cracks extending from the inside of the holding member 10 to the bottom surfaces 16B were likely to be smaller than that in the case of the bottom surfaces of the recesses formed by blasting. Furthermore, as described with reference to (B) and (C) of FIG. 3, the surface roughness of the bottom surfaces 16B was likely to be smaller than that of the bottom surfaces of the recesses formed by blasting.

As described above, in accordance with the holding member 10 included in the electrostatic chuck 1 of the present embodiment, at least the bottom surfaces 16B, among the side surfaces 16S and the bottom surfaces 16B formed in the holding surface 10f, contain gamma-type alumina that has a lower Young's modulus than alpha-type alumina, which is the main component of the holding member 10. Thus, among the thermal stress that is generated in the holding member 10 in the process of a thermal cycle, at least the thermal stress that is generated in the bottom surfaces 16B can be reduced. Therefore, generation of microcracks in the bottom surfaces 16B due to thermal stress can be suppressed, and thus, generation of particles can be suppressed.

In addition, in accordance with the holding member 10 included in the electrostatic chuck 1 of the present embodiment, the recesses 16 are formed in the processing target surface 10fp of the processing target member 10p, which contains alpha-type alumina as its main component, by irradiating the processing target surface 10fp with an ultrashort pulse laser beam. Thus, compared with the case where the recesses 16 are formed by collision of media (blasting), the probability of generation of microcracks in the recesses 16 can be reduced. As described above, in the present embodiment, by forming the recesses 16 by laser processing, gamma-type alumina can be contained in the bottom surfaces 16B, and the generation of microcracks due to thermal stress can be suppressed. In addition, generation of microcracks and accumulation of strain due to collision of media through blasting are also avoided, and thus, generation of particles can be suppressed.

In addition, in the holding member 10 included in the electrostatic chuck 1 of the present embodiment, the bottom surfaces 16B include, in addition to gamma-type alumina, the amorphous portion that has a lower Young's modulus than gamma-type alumina. Consequently, among the thermal stress that is generated in the holding member 10 in the process of the thermal cycle, the thermal stress that is generated in the bottom surfaces 16B can be further reduced. Further reduction of the thermal stress further suppresses the generation of microcracks, which in turn leads to further suppression of the generation of particles.

Since gamma-type alumina has a lower Young's modulus than alpha-type alumina, an appropriate amount of gamma-type alumina contained in the bottom surfaces 16B contributes to reduction of the thermal stress that is generated in the holding member 10 in the process of a thermal cycle. On the other hand, gamma-type alumina has a lower plasma resistance than alpha-type alumina, and thus, when an excessive amount of gamma-type alumina is contained in the bottom surfaces 16B, gamma-type alumina itself can be a generation source of particles. In the holding member 10 included in the electrostatic chuck 1 of the present embodiment, since the proportion of gamma-type alumina contained in the bottom surfaces 16B is 5% or more and 20% or less, the gamma-type alumina contained in the bottom surfaces 16B can contribute to reduction of the thermal stress while it is suppressed from becoming a generation source of particles.

In the holding surface 10f of the holding member 10, at least the bottom surfaces 16B are constituted by the first ceramic crystal grains, and a portion located further toward the inside than the holding surface 10f is constituted by the second ceramic crystal grains. The first grain diameters, which are the grain diameters of the first ceramic crystal grains, are smaller than the second grain diameters, which are the grain diameters of the second ceramic crystal grains. Accordingly, in the holding surface 10f, at least the bottom surfaces 16B are constituted by the first ceramic crystal grains having the first grain diameters, which are smaller than the second grain diameters, and thus, the sizes of particles that are generated from the holding surface 10f during use of the holding member 10 can be reduced. In addition, since the first ceramic crystal grains correspond to the ceramic crystal grains obtained by shaving portions of the second ceramic crystal grains, the bottom surfaces 16B constituted by the first ceramic crystal grains include ceramic crystal grains whose interiors (portions of the crystal grains that are located further toward the inside than the grain boundaries) are exposed toward the bottom surfaces 16B. In other words, the area of the grain boundaries exposed at the bottom surfaces 16B is reduced, so that the plasma resistance of the holding surface 10f including the above-described bottom surfaces 16B can be improved.

In the holding member 10, the grain diameters (the second grain diameters) of the ceramic crystal grains constituting the portion located further toward the inside than the holding surface 10f are larger than the grain diameters (the first grain diameters) of the ceramic crystal grains constituting the bottom surfaces 16B. When crystal grains have small grain diameters, there is a tendency for increased contact between the grains, resulting in an increase in heat loss. In the holding member 10, since the grain diameters of the ceramic crystal grains constituting the portion located further toward the inside than the holding surface 10f are the second grain diameters, which are larger than the first grain diameters, the contact between the grains in the portion is reduced, thereby reducing the heat loss in the portion.

In the holding member 10, the bottom surfaces 16B defining the recesses 16 are constituted by the first ceramic crystal grains. Thus, when the holding member 10 holds the semiconductor wafer W, which is a target object, the sizes of the particles generated from the holding surface 10f by the inert gas flowing between the semiconductor wafer W and the recesses 16 can be reduced.

In addition, in the holding member 10, at least the bottom surfaces 16B, among the side surfaces 16S and the bottom surfaces 16B, correspond to the laser-processed surfaces. Accordingly, the bottom surfaces 16B corresponding to the laser-processed surfaces are surfaces formed by finely shaving each ceramic crystal grain from a grain boundary toward the interior of the grain, and thus, the first grain diameters of the first ceramic crystal grains are smaller than the second grain diameters. Thus, it is possible to accurately provide the holding member 10 in which the first grain diameters are smaller than the second grain diameters. In addition, each of the laser-processed surfaces can have a smaller surface roughness than a blasted surface that has undergone blasting, in which a crystal grain is dislodged in its entirety along a grain boundary. In other words, an increase in surface area due to surface roughness can be reduced. As a result, the surface area that is to be subjected to plasma corrosion is reduced, and thus, generation of particles due to plasma corrosion can be suppressed.

In accordance with the electrostatic chuck 1 that includes the holding member 10, electrostatic attraction (an absorption force) is generated as a result of electric power being supplied to the electrostatic electrode 30, and the semiconductor wafer W can be held on the holding surface 10f by this electrostatic attraction. In addition, since the first grain diameters are smaller than the second grain diameters, the electrostatic chuck 1 having improved plasma resistance can be provided while the sizes of the particles that are generated from the holding surface 10f during use of the holding member 10 can be reduced.

### Modifications of Present Embodiment

The present invention is not limited to the above-described embodiment and can be implemented in various aspects without departing from the gist of the present invention. For example, the following modifications are also possible.

In the above-described embodiment, the ring-shaped projection 12, the plurality of projections 14, and the plurality of recesses 16 are formed on and in the holding surface 10f. However, the present invention is not limited to this. For example, the ring-shaped projection 12 does not need to be formed on the holding surface 10f, while the plurality of projections 14 and the plurality of recesses 16 are formed on and in the holding surface 10f.

In the above-described embodiment, the plurality of through-flow passages 22 are formed inside the holding member 10. However, the present invention is not limited to this. For example, in addition to the plurality of through-flow passages 22, a flow passage that connects the through-flow passages 22 to each other inside the holding member 10 and another flow passage that branches from the flow passage so as to be connected to the recesses 16 may be formed inside the holding member 10.

In the above-described embodiment, the recesses 16 are formed by irradiation with an ultrashort laser beam. However, the present invention is not limited to this. For example, as long as the recesses 16 contain gamma-type alumina, the recesses 16 may be formed by performing laser processing using a laser different from an ultrashort pulse laser or by performing any other processing different from the laser processing.

In the above-described embodiment, the proportion of gamma-type alumina contained in the bottom surfaces 16B is 5% or more and 20% or less. However, the present invention is not limited to this. For example, the proportion of gamma-type alumina contained in the bottom surfaces 16B may be less than 5% or may be more than 20%. Obviously, in order to enable the gamma-type alumina contained in the bottom surfaces 16B to contribute to reduction of the thermal stress while the gamma-type alumina is suppressed from becoming a generation source of particles, it is preferable that the proportion of gamma-type alumina contained in the bottom surfaces 16B be 5% or more and 20% or less.

In the above-described embodiment, a plurality of heater electrodes that are made of an electrically conductive material, such as tungsten or molybdenum, may be further provided inside the holding member 10. In such a case, when the target object is held by the holding member 10, the target object can be warmed by supplying electric power from an external power supply to the heater electrodes so as to cause the heater electrodes to generate heat.

In the above-described embodiment, a plate-shaped base member may be further joined to the rear surface of the holding member 10. In the case where a refrigerant flow passage is formed inside this base member, when the target object is held by the holding member 10, a refrigerant can cool the target object from the base member via the holding member by flowing inside the refrigerant flow passage.

Although the present aspect has been described above on the basis of the embodiment and the modifications, the embodiment of the above-described aspect is intended to facilitate understanding of the present aspect and does not limit the present aspect. The present aspect can be modified and improved without departing from the gist and the scope of the claims, and the present aspect includes equivalents thereof. In addition, if the technical features are not described as essential in the present specification, the technical features can be appropriately deleted.

The present invention can also be implemented in the following embodiments.

### Application Example 1

A holding member that contains alpha-type alumina as a main component and that is configured to hold a target object,
wherein the holding member has a holding surface that is a surface on which the target object is to be held,
wherein the holding surface has a projection and a recess formed thereon and therein, and
wherein a bottom surface that defines a bottom portion of the recess contains gamma-type alumina.

### Application Example 2

The holding member in accordance with application example 1,
wherein the bottom surface further includes an amorphous portion.

### Application Example 3

The holding member in accordance with application example 1 or application example 2,
wherein a proportion of gamma-type alumina contained in the bottom surface is 5% or more and 20% or less.

### Application Example 4

A method of manufacturing a holding member, the method comprising:
a recess formation step of forming a recess in a processing target surface of a member, the member containing alpha-type alumina as a main component, by irradiating the processing target surface with an ultrashort pulse laser beam.

### REFERENCE SIGNS LIST

1 electrostatic chuck
10 holding member
10b rear surface
10f holding surface
12 ring-shaped projection
14 projection
16 recess
16B bottom surface
16S side surface
22 through-flow passage
30 electrostatic electrode

1. A holding member that contains alpha-type alumina as a main component and that is configured to hold a target object,
wherein the holding member has a holding surface that is a surface on which the target object is to be held,
wherein the holding surface has a projection and a recess formed thereon and therein, and
wherein a bottom surface that defines a bottom portion of the recess contains gamma-type alumina.

2. The holding member in accordance with claim 1,
wherein the bottom surface further includes an amorphous portion.

3. The holding member in accordance with claim 1,
wherein a proportion of gamma-type alumina contained in the bottom surface is 5% or more and 20% or less.

4. A method of manufacturing a holding member, the method comprising:
a recess formation step of forming a recess in a processing target surface of a member, the member containing alpha-type alumina as a main component, by irradiating the processing target surface with an ultrashort pulse laser beam.

5. The holding member in accordance with claim 2,
wherein a proportion of gamma-type alumina contained in the bottom surface is 5% or more and 20% or less.
